(19) United States
(12) Patent Application Publication
(10) Pub. No.: US 2026/0368408 A1
(43) Pub. Date: Nov. 19, 2026

(54) METHOD OF DESIGNING LAYOUT OF MEMORY DEVICE AND METHOD OF MANUFACTURING MASK

(71) Applicant: Samsung Electronics Co., Ltd., Suwon-si (KR)

(72) Inventors: Ingyun Chung, Suwon-si (KR); Hyeonho Cho, Suwon-si (KR)

(21) Appl. No.: 19/413,565

(22) Filed: Dec. 9, 2025

(30) Foreign Application Priority Data
May 14, 2025 (KR) 10-2025-0062825
Jul. 11, 2025 (KR) 10-2025-0094074

(51) Int. Cl. G06F 30/392; G06F 30/398

(52) U.S. Cl. CPC G06F 30/392; G06F 30/398

(57) ABSTRACT

Provided is a method of designing a layout of a memory device, the method including identifying a plurality of unit cell pattern structures respectively corresponding to a plurality of cell layouts, identifying a plurality of Poisson's ratios respectively corresponding to the plurality of unit cell pattern structures, and identifying an isotropic optimal cell layout from among the plurality of cell layouts based on the plurality of Poisson's ratios.

### CROSS-REFERENCE TO RELATED APPLICATIONS

This application claims priority under 35 U.S.C. § 119 to Korean Patent Application Nos. 10-2025-0062825, filed on May 14, 2025, and 10-2025-0094074, filed on Jul. 11, 2025, in the Korean Intellectual Property Office, the disclosures of which are incorporated by reference herein in their entirety.

### BACKGROUND

A memory device may include a plurality of stacked structures stacked in a vertical direction. From among the plurality of stacked structures, a cell structure may include a plurality of cells repeatedly arranged along a certain pattern within a cell array region.

In the process of forming the cells, various types of processes (e.g., deposition process, etching process, etc.) may be performed. The performance of the various types of processes described above may result in mechanical stresses, which may cause buckling of the cell structure.

### SUMMARY

The disclosure relates to a method of designing a layout of a memory device and a method of manufacturing a corresponding mask, and more particularly, to a method of designing a layout that prevents buckling of a cell structure.

The disclosure provides a method of designing a layout of a memory device capable of suppressing buckling of a cell structure.

In addition, the technical goals to be achieved by the disclosure are not limited to the technical goals mentioned above, and other technical goals may be clearly understood by one of ordinary skill in the art from the following descriptions.

According to an aspect of the disclosure, there is provided a method of designing a layout of a memory device, the method including identifying a plurality of unit cell pattern structures respectively corresponding to a plurality of cell layouts, identifying a plurality of Poisson's ratios respectively corresponding to the plurality of unit cell pattern structures, and identifying an isotropic optimal cell layout from among the plurality of cell layouts based on the plurality of Poisson's ratios, wherein the identifying of the isotropic optimal cell layout includes identifying the maximum Poisson's ratio from among the plurality of Poisson's ratios, and identifying, from among the plurality of cell layouts, a cell layout corresponding to the maximum Poisson's ratio as the isotropic optimal cell layout, the isotropic optimal cell layout is a buckling minimization cell layout corresponding to an isotropic cell array region, and a plurality of horizontal cell pitches respectively corresponding to the plurality of cell layouts are substantially the same.

According to another aspect of the disclosure, there is provided a method of designing a layout of a memory device, the method including identifying a plurality of unit cell pattern structures respectively corresponding to a plurality of cell layouts, identifying a plurality of Poisson's ratios respectively corresponding to the plurality of unit cell pattern structures, and identifying an anisotropic optimal cell layout from among the plurality of cell layouts based on the plurality of Poisson's ratios, wherein the identifying of the anisotropic optimal cell layout includes: identifying the minimum Poisson's ratio from among the plurality of Poisson's ratios, and identifying, from among the plurality of cell layouts, a cell layout corresponding to the minimum Poisson's ratio as the anisotropic optimal cell layout, the anisotropic optimal cell layout is a buckling minimization cell layout corresponding to an anisotropic cell array region, the 2D aspect ratio of a horizontal cross-section of the anisotropic cell array region is 1:R (R is a real number greater than 1), and a plurality of horizontal cell pitches respectively corresponding to the plurality of cell layouts are substantially the same.

According to another aspect of the disclosure, there is provided a method of manufacturing a mask, the method including preparing a plurality of cell layouts satisfying a horizontal cell pitch of a memory device, identifying a plurality of unit cell pattern structures respectively corresponding to the plurality of cell layouts based on repeating patterns of the plurality of cell layouts, identifying a plurality of Poisson's ratios respectively corresponding to the plurality of unit cell pattern structures, identifying an optimal cell layout for the memory device from among the plurality of cell layouts based on the plurality of Poisson's ratios, and manufacturing a mask corresponding to the optimal cell layout, wherein the identifying of the optimal cell layout includes: when the memory device includes an isotropic cell array region, identifying the maximum Poisson's ratio from among the plurality of Poisson's ratios, and identifying, from among the plurality of cell layouts, a cell layout corresponding to the maximum Poisson's ratio as the optimal cell layout, when the memory device includes an anisotropic cell array region, identifying the minimum Poisson's ratio from among the plurality of Poisson's ratios, and identifying, from among the plurality of cell layouts, a cell layout corresponding to the minimum Poisson's ratio as the optimal cell layout.

### BRIEF DESCRIPTION OF THE DRAWINGS

Implementations of the disclosure will be more clearly understood from the following detailed description taken in conjunction with the accompanying diagrams.

FIG. 1 is a block diagram showing a computing system for designing a layout of a memory device, according to some implementations.

FIG. 2 is a flowchart for describing a method of manufacturing a mask, according to some implementations.

FIG. 3 is a plan view for describing a plurality of cell layouts, according to some implementations.

FIG. 4 is a cell layout image according to some implementations and a cross-sectional view of a cell structure corresponding thereto.

FIGS. 5A and 5B are plan views for describing a method of identifying a unit cell pattern structure, according to some implementations.

FIG. 6 is a plan view for describing a method of identifying a Poisson's ratio of a unit cell pattern structure, according to some implementations.

FIGS. 7A and 7B are plan views for describing a method of identifying a Poisson ratio, according to some implementations.

FIG. 8 is a graph showing a result of a simulation according to some implementations.

FIG. 9 is a table for describing a method of identifying an optimal cell layout, according to some implementations.

FIG. 10 is a flowchart for describing a method of identifying an optimal cell layout, according to some implementations.

FIGS. 11A and 11B are cross-sectional views for describing a cell array region of a memory device according to some implementations.

FIGS. 12A, 12B, 13A and 13B are plan views for describing a method of identifying a deformed 2D aspect ratio, according to some implementations.

FIG. 14 is a flowchart showing a method of manufacturing a mask, according to some implementations.

### DETAILED DESCRIPTION

In the disclosure, a “memory device” may mean a semiconductor device capable of reading/writing data, and a device including cells (memory cells). For example, the memory device may be a 3D NAND flash memory device. However, the memory device is not limited to a 3D NAND flash memory device, and may be implemented as various types of volatile or non-volatile memory devices. For example, the volatile memory device may be implemented as a dynamic random access memory (DRAM) or a static random access memory (SRAM), and the non-volatile memory device may be implemented as an electrically erasable programmable read-only memory (EEPROM) or a magnetic random access memory (MRAM). In this disclosure, an example in which the memory device is a 3D NAND flash memory device will be mainly described.

In the disclosure, “cell layout” may mean design information regarding the arrangement method of a plurality of cells. In detail, the cell layout may include information regarding a repetitive arrangement structure of plurality of cells, the number of a plurality of cells, and the shapes of the plurality of cells. For example, when the memory device is a 3D NAND flash memory device, the cell layout may include information regarding a repetitive arrangement structure of a plurality of vertical channel structures, the number of the plurality of vertical channel structures, and the shapes of the plurality of vertical channel structures, within a cell array region.

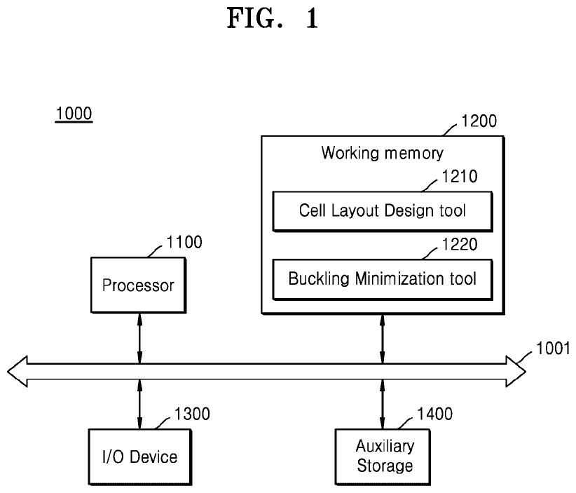

FIG. 1 is a block diagram showing a computing system 1000 that performs designing of a layout of a memory device, according to some implementations.

Referring to FIG. 1, the computing system 1000 may include at least one processor 1100, a working memory 1200, an input/output device 1300, and an auxiliary storage device 1400 that are connected to a system bus 1001.

Here, the computing system 1000 may be a dedicated device for designing a layout of a memory device or a dedicated device for performing a semiconductor designing including the memory device. For example, the computing system 1000 may include various design and verification simulation programs. The processor 1100, the working memory 1200, the input/output device 1300, and the auxiliary storage device 1400 are electrically connected to one another and may exchange data with one another through the system bus 1001. Meanwhile, the system bus 1001 may further include arbitration means for efficient management.

The processor 1100 may be implemented to execute at least one instruction. For example, the processor 1100 may be implemented to execute software (applications, operating systems (OS), device drivers) to be executed on the computing system 1000. The processor 1100 may execute an OS loaded into the working memory 1200. The processor 1100 may execute various application programs that will be driven based on the OS. For example, the processor 1100 may be a central processing unit (CPU), a microprocessor, an application processor (AP), or any similar processing device.

The working memory 1200 may be implemented to store at least one instruction. For example, the working memory 1200 may be loaded with an OS or application programs. Applications may be loaded into the working memory 1200 to be selected by a user or to provide basic services. In particular, a cell layout design tool 1210 for designing the layout of a memory device and a buckling minimization tool 1220 for identifying a layout capable of minimizing buckling from among a plurality of cell layouts may be loaded from the auxiliary storage device 1400 to the working memory 1200. Also, the working memory 1200 may further be loaded with OPC tools for correcting the layout by considering the optical proximity effect. Also, the working memory 1200 may be a volatile memory such as DRAM, SRAM, etc., or a non-volatile memory such as flash memory, MRAM, etc.

The cell layout design tool 1210 may generate a plurality of cell layouts for a memory device. The horizontal cell pitch of each of the plurality of cell layouts may be substantially equal to each other. Generally, in this disclosure two variables are substantially equal to each other if the values of the two variables are equal or if the difference between the values of the two variables is within 5% of the value of either one of the two variables. The buckling minimization tool 1220 may predict (or identify) a cell layout with the highest buckling suppression capability from among a plurality of cell layouts based on a numerical method or an analytical method.

The input/output device 1300 may control user inputs and user outputs from user interface devices. For example, the input/output device 1300 may be equipped with an input means such as a keyboard, a keypad, a mouse, a touch screen, etc. to receive information from a designer. For example, a designer may input information regarding a horizontal cell pitch that each of a plurality of cell layouts needs to satisfy, information regarding the geometric structure of a cell array region of a memory device, etc., through the input/output device 1300. The input/output device 1300 is equipped with an output means such as a printer, a display, etc., and may display the processing process and results of the cell layout design tool 1210 or the buckling minimization tool 1220.

The auxiliary storage device 1400 may be provided as a storage medium of the computing system 1000. The auxiliary storage device 1400 may store application programs and various data. The auxiliary storage device 1400 may be provided in the form of a large-capacity storage device such as a memory card (MMC, eMMC, SD, Micro SD, etc.), a hard disk drive (HDD), a solid state drive (SSD), a universal flash storage (UFS), etc.

The computing system 1000 may identify an optimal cell layout that may minimize buckling of a cell structure. Also, the computing system 1000 may also generate mask data corresponding to the optimal cell layout. The method of identifying an optimal cell layout and the method of generating mask data performed by the computing system 1000 will be described in detail in the descriptions of drawings below.

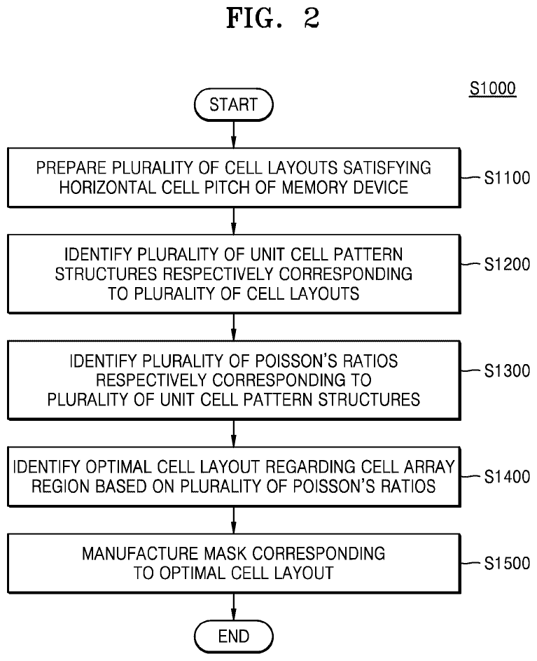

FIG. 2 is a flowchart for describing a method S1000 for designing a mask, according to some implementations.

Referring to FIG. 2, in operation S1100, a plurality of cell layouts satisfying the horizontal cell pitch of a memory device may be prepared.

In the disclosure, the horizontal cell pitch may mean a horizontal distance between two cells arranged adjacent to each other. The horizontal cell pitch may be determined before designing the cell layout based on limitations of photolithography resolution, signal interference between adjacent cells, prevention of leakage current, and target capacity and target performance of the memory device, etc.

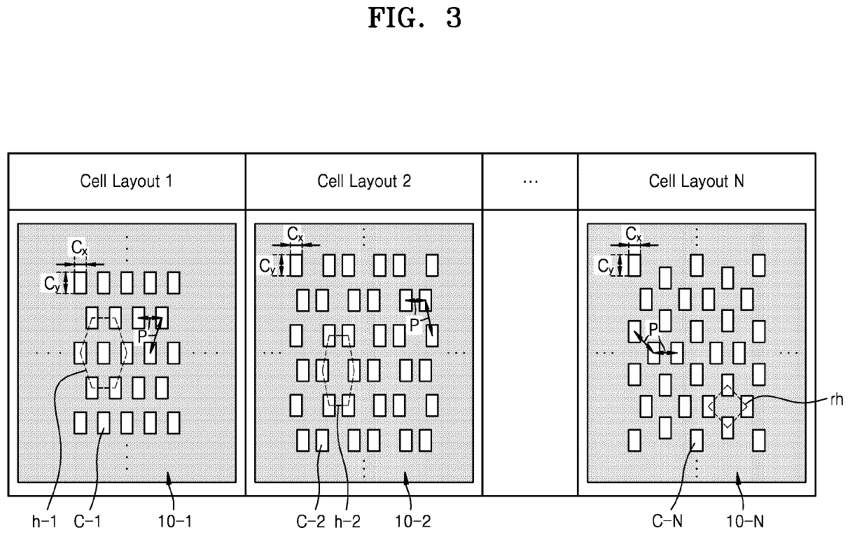

The plurality of cell layouts may have different 2-dimensional cell arrangement shapes while satisfying the same horizontal cell pitch. For example, a particular cell layout may include a 2-dimensional cell arrangement in a hexagonal pattern, while another cell layout may include a 2-dimensional cell arrangement in a rhombic pattern. The plurality of cell layout will be described in detail in the description of FIG. 3 below.

Next, in operation S1200, a plurality of unit cell pattern structures respectively corresponding to the plurality of cell layouts may be identified.

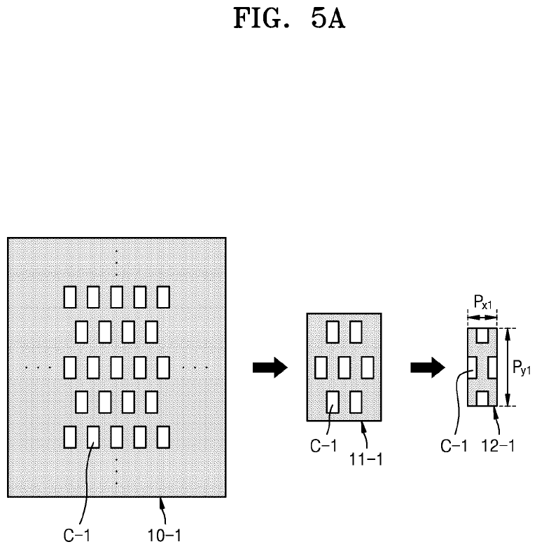

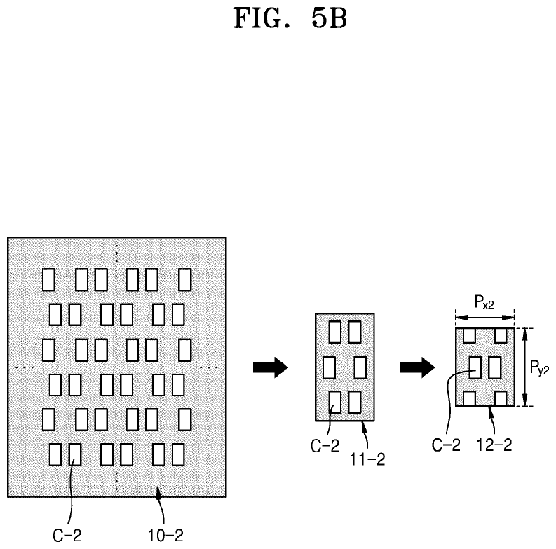

In the disclosure, the “unit cell pattern structure” may be a structure identified from a cell layout as the minimum unit to be subject to Poisson ratio calculation. Here, the number of cells per unit area included in each of the plurality of unit cell pattern structures may be substantially the same. Here, when two numbers of cells per unit area are literally the same or the difference between the two numbers is less than 5% of either of the two numbers, it may be deemed that “the number of cells per unit area are substantially the same”. A method of identifying a plurality of unit cell pattern structures respectively corresponding to a plurality of cell layouts will be described in detail in the description of FIGS. 5A and 5B below.

Next, in operation S1300, a plurality of Poisson's ratios respectively corresponding to a plurality of unit cell pattern structures may be identified.

The Poisson's ratio is an indicator of 2-dimensional deformation characteristics of a particular structure. The Poisson's ratio may mean a ratio between the degree of deformation in a first direction and the degree of deformation in a second direction of a particular structure when deformation of the particular structure occurs due to stress. Here, the second direction is a direction perpendicular to the first direction. In theory, the Poisson's ratio has a positive value greater than or equal to 0 and less than or equal to 0.5. In detail, the Poisson's ratio may be calculated according to Equation 1 below.

$$v = - \frac{{ϵ}_{y}}{{ϵ}_{x}} \qquad [ Equation 1 ]$$

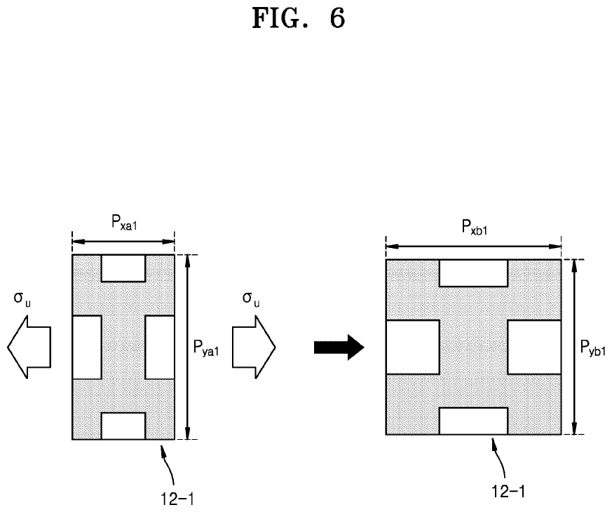

Here, ν may denote the Poisson's ratio, εₓ may denote the deformation in the first horizontal direction (x direction), and ε_{y} may denote the deformation in the second horizontal direction (y direction). For example, when the Poisson's ratio of a particular structure is 0.5 and a stress in the first horizontal direction is applied to the particular structure, the deformation of the particular structure in the first horizontal direction may be twice the deformation of the particular structure in the second horizontal direction. Conversely, when the Poisson's ratio of a particular structure is 0 and a stress in the first horizontal direction is applied to the particular structure, the stress in the second horizontal direction may be 0. A method of identifying a plurality of Poisson's ratios respectively corresponding to a plurality of unit cell pattern structures will be described in detail in the description of FIGS. 6 to 8.

Next, in operation 1400, an optimal cell layout for a cell array region may be identified based on a plurality of Poisson ratios.

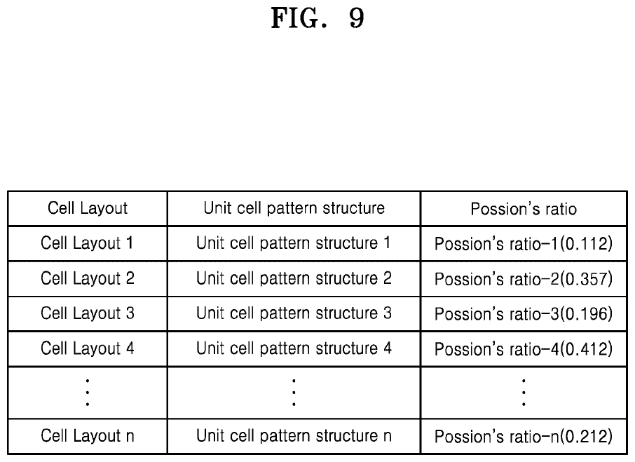

According to some implementations, when a memory device includes an anisotropic cell array region, an anisotropic optimal cell layout may be identified. According to some implementations, when a memory device includes an isotropic cell array region, an isotropic optimal cell layout may be identified. According to the disclosure, an isotropic cell array region may refer to a cell array region having a 2D aspect ratio of substantially 1:1. Also, an anisotropic cell array region may refer to a cell array region with a 2D aspect ratio other than 1:1. For example, the dimensional aspect ratio of an anisotropic cell array region may be 1:R (where R is a real number greater than 1). A method of identifying an optimal cell layout based on a plurality of Poisson ratios will be described in detail in the description of FIGS. 9 to 13B below.

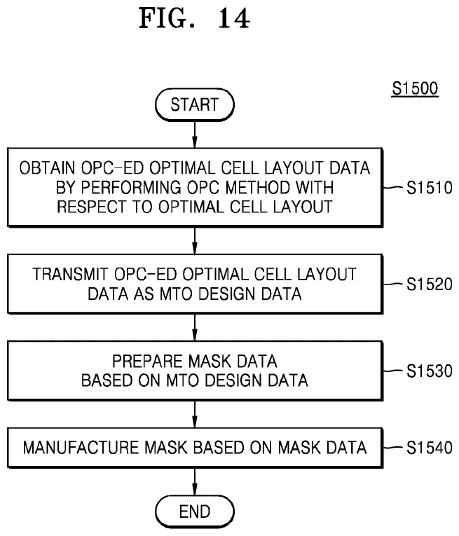

Next, in operation 1500, a mask corresponding to an optimal cell layout may be manufactured. A method of manufacturing a mask will be described in detail in the description of FIG. 14 below.

According to a method of designing a layout of a memory device and a method of manufacturing a mask, according to some implementations, a cell layout that may minimize buckling of a cell structure may be quickly identified. In detail, the method may predict the degree of thermal deformation that may occur when a cell layout corresponding to a particular unit cell pattern structure is applied to a cell array region of a memory device based on a Poisson's ratio, and may quickly identify a cell layout having the greatest buckling suppression force based on the predicted degree of thermal deformation. Therefore, the method may prevent misalignment that may occur between a plurality of vertically stacked structures by minimizing buckling of a cell structure.

FIG. 3 is a plan view for describing a plurality of cell layouts according to some implementations.

Referring to FIG. 3, a plurality of cell layouts (e.g., first to N-th cell layouts 10-1, 10-2, . . . and, 10-N) may be prepared. A plurality of cell layouts may be designed to satisfy pre-set design rules and have substantially identical horizontal cell pitches P. Here, a horizontal cell pitch P may mean the horizontal distance between two adjacent cells from among a plurality of cells arranged within a particular cell layout. For example, the horizontal cell pitch P may be the horizontal distance between center points of two cells adjacent to each other.

The horizontal cell widths of the plurality of cell layouts may also be substantially identical to each other. For example, a plurality of first cells C-1 included in a first cell layout 10-1 may have a width of “Cx” in the first horizontal direction and a width of “Cy” in the second horizontal direction. Also, a plurality of second cells C-2 included in a second cell layout 10-2 and a plurality of N-th cells C—N included in an N-th cell layout 10-N may also have a width of “Cx” in the first horizontal direction and a width of “Cy” in the second horizontal direction.

Although FIG. 3 only shows that each of a plurality of cells C-1, C-2, and CN has a rectangular shape, it is merely an example. For example, the shape of a cell included in a cell layout may be implemented in various shapes, such as a hexagonal shape or a circular shape.

A plurality of cell layouts may each has a different 2-dimensional cell arrangement shape. According to some implementations, the first cell layout 10-1 may have a 2-dimensional cell arrangement shape having a first hexagonal pattern h-1, the second cell layout 10-2 may have a 2-dimensional cell arrangement shape having a second hexagonal pattern h-2, and the N-th cell layout 10-N may have a 2-dimensional cell arrangement shape having a rhombus pattern rh. Here, the expression “a plurality of cells are arranged in a 2-dimensional cell arrangement having a hexagonal pattern” may mean that a plurality of cells are arranged at each of six vertices included in a hexagon. In the 2-dimensional cell arrangement of the first hexagonal pattern h-1, two hexagons adjacent to each other may partially overlap, and, in the 2-dimensional cell arrangement of the second hexagonal pattern h-2, two hexagons adjacent to each other may not overlap each other. The term “hexagonal pattern” may be replaced by various terms such as “honeycomb pattern,” but in this disclosure, the term “hexagonal pattern” will be used.

Although FIG. 3 only shows the 2-dimensional cell arrangement shapes of the first hexagonal pattern h-1, the second hexagonal pattern h-2, and the rhombus pattern rh, these are merely examples of 2-dimensional cell arrangement shapes. Within a range satisfying a particular horizontal cell width and a particular horizontal cell pitch, a plurality of cell layouts including 2-dimensional cell arrangement forms of various patterns may be prepared. For example, a cell layout including a 2-dimensional cell layout of a square pattern and a 2-dimensional cell layout of a triangular pattern may also be prepared.

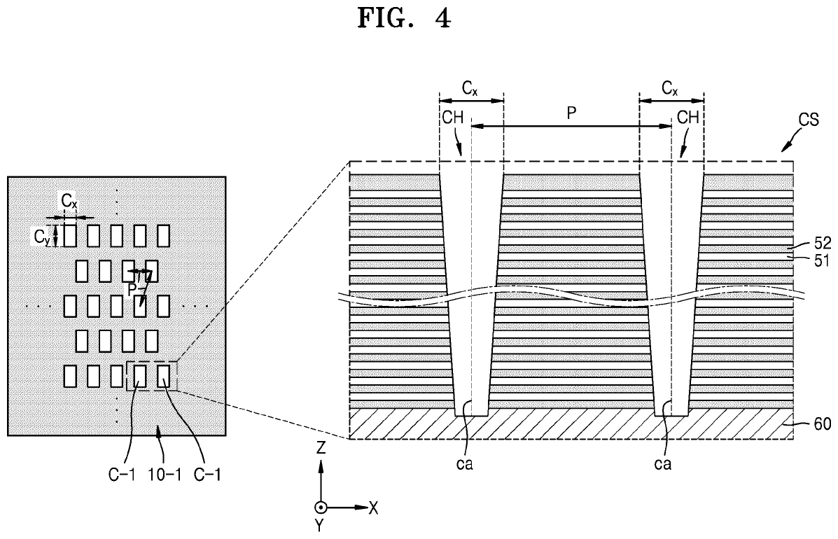

FIG. 4 is a cross-sectional view of a cell layout and a corresponding cell structure according to some implementations.

Referring to FIG. 4, a cell structure CS may be a structure corresponding to the first cell layout 10-1. In detail, when the first cell layout 10-1 is applied to a manufacturing process of a memory device, the cell structure CS of FIG. 4 may represent an intermediate structure that may be formed in an intermediate stage of the manufacturing process of the memory device.

The cell structure CS may include a substrate 60, a mold insulation layer 51 and a sacrificial layer 52 alternately arranged in the vertical direction (Z direction) on the substrate 60, and a channel hole structure CH formed by vertically penetrating through the mold insulation layer 51 and the sacrificial layer 52. The channel hole structure CH may penetrate through at least a portion of the substrate 60.

The channel hole structure CH may be a structure corresponding to a first cell C-1 of the first cell layout 10-1. In detail, when the first cell layout 10-1 is applied to a manufacturing process of a memory device, the 2-dimensional arrangement structure of a plurality of channel hole structures CH may be substantially identical to the 2-dimensional arrangement structure of the plurality of first cells C-1. According to some implementations, the plurality of first cells C-1 may be repeatedly arranged along a first hexagonal pattern in a first cell layout 10-1, and, in this case, the plurality of channel hole structures CH may also be repeatedly arranged along the first hexagonal pattern within a cell array region of a cell structure CS.

According to some implementations, the horizontal width of the channel hole structure CH may correspond to the horizontal cell width of the first cell C-1. In detail, the width of the upper portion of the channel hole structure CH in the first horizontal direction may be substantially identical to a width Cₓ of the first cell C-1 the first horizontal direction, and the width of the upper portion of the channel hole structure CH in the second horizontal direction may be substantially identical to the width Cy of the first cell C-1 in the second horizontal direction. Also, the pitch between the central axes ca of two channel hole structures CH adjacent to each other may be substantially identical to the horizontal cell pitch P of the first cell C-1. In the disclosure, two distances (e.g., widths, pitches) may be considered to be “substantially identical to each other” not only when they are literally identical to each other, but also when the difference between the two distances is 5% or less of either of the two distances.

The channel hole structures CH may be formed through a high aspect ratio anisotropic etching process. By performing the etching process, impurities (e.g., hydrogen molecules, hydrogen ions, hydrogen radicals, etc.) may be formed on sidewalls of the mold insulation layer 51. To remove impurities formed on the sidewalls of the mold insulation layer 51, a heat treatment process may be performed on the cell structure CS. Thermal stresses resulting from the heat treatment process may deform the cell structure CS. As a result, the 2D aspect ratio of the cell structure CS may be changed, and the buckling suppression effect against mechanical stress that may occur during the manufacturing process may be improved by deforming the 2D aspect ratio to be close to 1:1.

A method of designing a layout according to some implementations may improve the buckling suppression effect of the cell structure CS by designing a cell layout of a memory device while considering even a 2D aspect ratio that changes due to thermal deformation. Although FIG. 4 shows only the cell structure CS used in a 3D NAND flash memory device, this is merely an example. The first cell layout 10-1 may be applied to the cell structure CS of various memory devices such as DRAM devices and MRAM devices.

FIGS. 5A and 5B are plan views for describing a method of identifying a unit cell pattern structure, according to some implementations. FIG. 5A is a plan view for describing a method of identifying a first unit cell pattern structure 12-1 corresponding to the first cell layout 10-1, and FIG. 5B is a plan view for describing a method of identifying a second unit cell pattern structure 12-2 corresponding to the second cell layout 10-2.

Referring to FIGS. 5A and 5B, a first hexagonal repeating pattern 11-1 may be identified from the first cell layout 10-1, and a second hexagonal repeating pattern 11-2 may be identified from the second cell layout 10-2. The process of identifying a repetitive pattern from a particular cell layout may be performed based on an analysis method based on a Fourier transformation for a 2-dimensional image, an autocorrelation analysis method, or an analysis method based on a convolutional neural network (CNN). The method of identifying a repeating pattern is not limited to the examples described above and may be performed based on various methods.

Next, based on a repeating pattern, a unit cell pattern structure may be identified. According to some implementations, based on the first hexagonal repeating pattern 11-1, the first unit cell pattern structure 12-1 corresponding to the first cell layout 10-1 may be identified, and, based on the second hexagonal repeating pattern 11-2, the second unit cell pattern structure 12-2 corresponding to the second cell layout 10-2 may be identified. Here, the number of cells per unit area of the first unit cell pattern structure 12-1 may be substantially identical to the number of cells per unit area of the second unit cell pattern structure 12-2.

According to some implementations, a first area of the first unit cell pattern structure 12-1 may be a product (Pₓ₁×P_{y1}) of a width Pₓ₁ in the first horizontal direction and a width P_{y1} in the second horizontal direction, and a second area of the second unit cell pattern structure 12-2 may be a product (Pₓ₂×P_{y2}) of a width Pₓ₂ in the first horizontal direction and a width P_{y2} in the second horizontal direction. As shown in FIG. 5A, two first cells C-1 divided in half by a straight line in the first horizontal direction and two first cells C-1 divided in half by a straight line in the second horizontal direction may be arranged within the first unit cell pattern structure 12-1. Therefore, the number of cells per unit area of the first unit cell pattern structure 12-1 may be

$$\frac{2}{{P}_{x 1} \times {P}_{y 1}} .$$

By the same principle, the number of cells per unit area of the second unit cell pattern structure 12-2 may be

$$\frac{4}{{P}_{x 2} \times {P}_{y2}} ,$$

which may be equal to the number of cells per unit area of the first unit cell pattern structure 12-1.

In other words, a unit cell pattern structure may be identified (or generated) based on a repeating pattern of a particular cell layout within a range where the number of cells per unit area satisfies a reference value. For example, when the reference value is “2 (cells)/nm²”, the number of cells per unit area of each of the plurality of unit cell pattern structures (e.g., the first unit cell pattern structure 12-1 and the second unit cell pattern structure 12-2) may be substantially equal to 2 (cells)/nm². To this end, the values of the first horizontal direction width Pₓ₁ and the second horizontal direction width P_{y1} may be set such that the first area of the first unit cell pattern structure 12-1 is 1 nm², and values of the first horizontal direction width Pₓ₂ and the second horizontal direction width P_{y2} may be set such that the second area of the second unit cell pattern structure 12-2 is 2 nm².

According to some implementations, each of the plurality of unit cell pattern structures (e.g., the first unit cell pattern structure 12-1 and the second unit cell pattern structure 12-2) may have the same geometric shape. For example, as shown in FIGS. 5A and 5B, both the first unit cell pattern structure 12-1 and the second unit cell pattern structure 12-2 may have a rectangular shape. In another example, all of the plurality of unit cell pattern structures may have various geometric shapes, such as equilateral triangles or pentagons.

When a plurality of unit cell pattern structures are identified, a plurality of Poisson's ratios respectively corresponding to the plurality of unit cell pattern structures may be identified (or calculated). A unit cell pattern structure to calculate a Poisson's ratio may be a representative structure that simplifies the repetitive structure of a cell layout. By utilizing the unit cell pattern structure, a Poisson's ratio may be quickly calculated, and a calculated Poisson's ratio may be utilized to predict the thermal deformation characteristics of a cell structure to which a corresponding cell layout is applied. In the descriptions of FIGS. 6 to 8 below, a method of identifying a Poisson's ratio corresponding to a unit cell pattern structure will be described.

FIG. 6 is a plan view for describing a method of identifying a Poisson's ratio of a unit cell pattern structure according to some implementations.

Referring to FIG. 6, when a uniaxial tensile loading σᵤ is applied to the first unit cell pattern structure 12-1, the 2D aspect ratio of the first unit cell pattern structure 12-1 may be deformed. The Poisson's ratio may be determined based on the deformation of unit cell pattern structure in the first horizontal direction and the deformation of unit cell pattern structure in the second horizontal direction, as described in Equation 1 above. Here, the uniaxial tensile loading Ou may mean a tensile loading that is applied only in a direction parallel to a particular axial direction.

According to some implementations, when the uniaxial tensile loading σᵤ is applied in the first horizontal direction to the first unit cell pattern structure 12-1, the width of the first horizontal direction of the first unit cell pattern structure 12-1 may be changed from an initial horizontal width Pₓₐ₁ to a deformed horizontal width P_{xb1}, and the width of the second horizontal direction of the first unit cell pattern structure 12-1 may be changed from an initial vertical width P_{ya1} to a deformed vertical width P_{yb1}. In general, when the uniaxial tensile loading σᵤ is applied in the first horizontal direction to the first unit cell pattern structure 12-1, a deformed horizontal width P_{xb1} may be greater than the initial horizontal width Pₓₐ₁, and a deformed vertical width P_{yb1} may be less than an initial vertical width P_{ya1}. Here, the degree of deformation in the first horizontal direction εₓ and the degree of deformation in the second horizontal direction ε_{y} may be determined based on Equation 2 below.

$${ϵ}_{x} = \frac{{P}_{xb 1} - {P}_{xa 1}}{{P}_{xa 1}} \qquad [ Equation 2 ]$$

$${ϵ}_{y} = \frac{{P}_{yb 1} - {P}_{ya 1}}{{P}_{ya 1}}$$

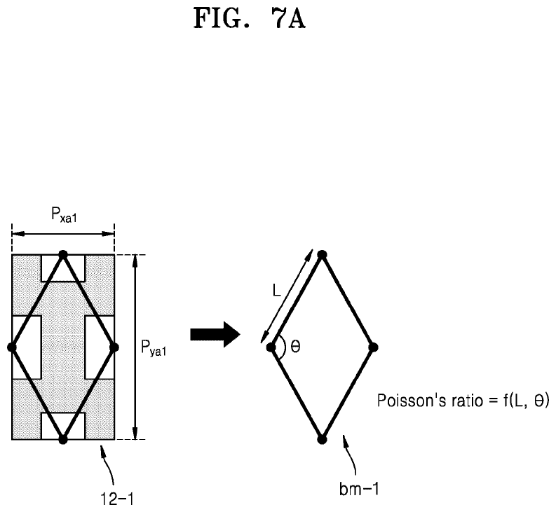

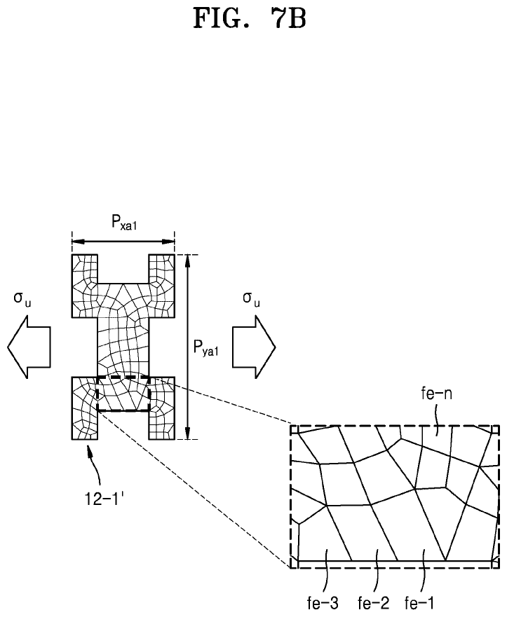

The degree of deformation εₓ of the first unit cell pattern structure 12-1 in the first horizontal direction and the degree of deformation ε_{y} of the first unit cell pattern structure 12-1 in the second horizontal direction are determined, a first Poisson's ratio corresponding to the first unit cell pattern structure 12-1 may be determined based on the degree of deformation εₓ in the first horizontal direction and the degree of deformation ε_{y} in the second horizontal direction. The method of identifying a Poisson's ratio as described above may be performed based on a numerical method or an analytical method. In the description of FIG. 7A described below, a method for identifying a Poisson's ratio based on an analytical method will be briefly described, and in the description of FIG. 7B, a method of identifying a Poisson's ratio based on a numerical method will be briefly described.

FIGS. 7A and 7B are plan views for describing a method of identifying a Poisson ratio according to some implementations.

Referring to FIG. 7A, a first Poisson's ratio corresponding to the first unit cell pattern structure 12-1 may be identified based on an analytical method. According to the disclosure, an analytical method of deriving a Poisson's ratio may mean a method of deriving a Poisson's ratio based on a pre-set function.

Within a unit cell pattern structure, a plurality of cells may be arranged to satisfy a horizontal cell pitch from several nm to dozens of nm. When a tensile loading is applied to a unit cell pattern structure that satisfies a horizontal cell pitch from several nm to dozens of nm, the deformation that occurs in the unit cell pattern structure may be very similar to the deformation that occurs in a rod model. Here, the rod model may include a plurality of rods connected to each other, and any one of the plurality of rods may 2-dimensionally connect two cells arranged adjacent to each other from among a plurality of cells arranged within the unit cell pattern structure.

As shown in FIG. 7A, the first unit cell pattern structure 12-1 may be simplified into a first rod model bm-1 including four rods connected to one another, and the Poisson's ratio of the first rod model bm-1 may be determined based on a Poisson's ratio function corresponding to the first rod model bm-1. For example, the Poisson's ratio function corresponding to the first rod model bm-1 may be a function that receives the length L of a rod and an angle θ between two rods adjacent to each other as input and outputs the Poisson's ratio of the first rod model bm-1.

As described above, based on an analytical method of approximating a unit cell pattern structure with a rod model, a Poisson's ratio corresponding to a particular unit cell pattern structure may be quickly calculated. FIG. 7A shows only a method of approximating the unit cell pattern structure with a rhombus-shaped bar model, but this is merely an example. Each of the plurality of unit cell pattern structures may be approximated with various types of rod models, such as a hexagonal rod model and a rectangular rod model, and the Poisson's ratio of each of the plurality of unit cell pattern structures may of course be determined based on a Poisson's ratio function corresponding to each of the various types of rod models.

Referring to FIG. 7B, the first Poisson's ratio corresponding to the first unit cell pattern structure 12-1 may be identified based on a numerical method. According to the disclosure, a numerical method of deriving a Poisson's ratio may mean a method of deriving a Poisson's ratio through a complex numerical analysis process. For example, a numerical method of deriving a Poisson's ratio may include a method of deriving a Poisson's ratio based on performing a simulation that simulates the phenomenon of applying a uniaxial tensile loading σᵤ to a unit cell pattern structure. The simulation may include a finite element method (FEM) simulation. However, the simulation method of the disclosure is not limited to the finite element method, and the simulation method may include various simulations such as the finite difference method (FDM) simulation and the finite volume method (FVM) simulation.

According to some implementations, a first Poisson's ratio corresponding to the first unit cell pattern structure 12-1 may be identified based on a finite element method simulation. In this case, the first unit cell pattern structure 12-1 may be converted into a first finite element mesh structure 12-1′. In the process of converting the first unit cell pattern structure 12-1 into the first finite element mesh structure 12-1′, the first unit cell pattern structure 12-1 may be divided into a plurality of finite elements.

The first finite element mesh structure 12-1′ may include a plurality of finite elements (e.g., the first to n-th finite elements fe-1, fe-2, fe-3, . . . , and fe-n). In performing a finite element method simulation, each of the plurality of finite elements may be a basic unit of numerical analysis. In detail, in performing a simulation in which the uniaxial tensile loading Ou is applied to the first finite element mesh structure 12-1′, numerical analysis may be performed for each of the first to n-th finite elements fe-1, fe-2, fe-3, . . . , and fe-n. During the simulation process, the deformation of each of the first to n-th finite elements fe-1, fe-2, fe-3, . . . , and fe-n may be calculated as a result of numerical analysis. Based on the deformation of each of the first to n-th finite elements fe-1, fe-2, fe-3, . . . , and fe-n, the overall deformation of the first finite element mesh structure 12-1′ may be determined. Based on the overall deformation of the first finite element mesh structure 12-1′, the deformation of a width Pₓₐ₁ in the first horizontal direction and the deformation of a width P_{ya1} in the second horizontal direction may be calculated, and, based on the deformation of the width Pₓₐ₁ in the first horizontal direction and the deformation of the width P_{ya1} in the second horizontal direction, the first Poisson's ratio corresponding to the first unit cell pattern structure 12-1 may be determined.

Although description of FIGS. 7A and 7B provides examples of analytical and numerical methods for identifying the first Poisson ratio corresponding to the first unit cell pattern structure 12-1, it is merely for convenience of explanation. It goes without saying that second to n-th Poisson's ratios corresponding to second to n-th unit cell pattern structures 12-2, . . . , and 12-n may be identified based on the same method as described above.

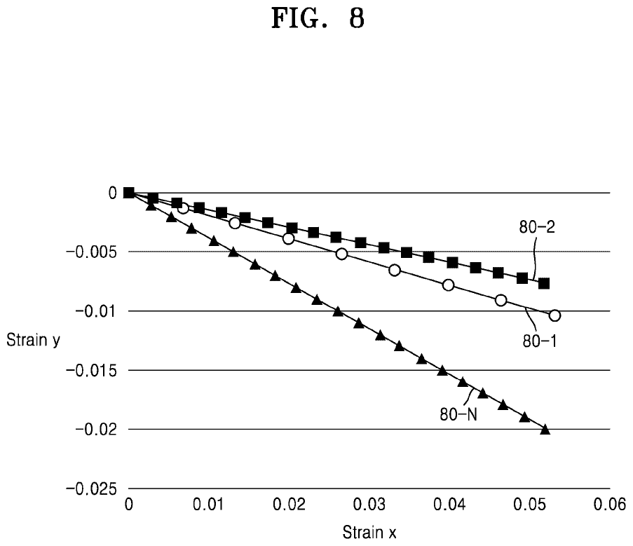

FIG. 8 is a graph showing a result of a simulation according to some implementations.

Referring to FIG. 8, a first straight line 80-1 represents a result of a simulation regarding the first unit cell pattern structure 12-1, a second straight line 80-2 represents a result of a simulation regarding a second unit cell pattern structure 12-2, and an N-th straight line 80-N represents a result of a simulation regarding an N-th unit cell pattern structure. The X-axis of the graph represents the deformation in the first horizontal direction, and the Y-axis of the graph represents the deformation in the second horizontal direction.

The absolute value of the slope of the first straight line 80-1 may be the first Poisson's ratio corresponding to the first unit cell pattern structure 12-1, the absolute value of the slope of the second straight line 80-2 may be the second Poisson's ratio corresponding to the second unit cell pattern structure 12-2, and the absolute value of the slope of the N-th straight line 80-N may be an N-th Poisson's ratio corresponding to an N-th unit cell pattern structure. As described above, a plurality of Poisson's ratios respectively corresponding to a plurality of unit cell pattern structures may be quickly identified based on slopes of a plurality of straight lines obtained through performing simulations.

FIG. 9 is a table for describing a method of identifying an optimal cell layout, according to some implementations. Referring to FIG. 9, an optimal cell layout may be identified based on a plurality of Poisson ratios.

According to some implementations, a memory device may include an isotropic cell array region. In this case, the maximum Poisson's ratio from among the plurality of Poisson's ratios may be identified, and a cell layout corresponding to the maximum Poisson's ratio may be identified as the optimal cell layout. According to some implementations, the memory device may include an anisotropic cell array region. In this case, the minimum Poisson's ratio from among the plurality of Poisson's ratios may be identified, and a cell layout corresponding to the minimum Poisson's ratio may be identified as the optimal cell layout.

According to the table shown in FIG. 9, from among the plurality of Poisson's ratios, a first Poisson's ratio Poisson's ratio-1 may be identified as the minimum Poisson's ratio, and a first cell layout 10-1 corresponding to the first Poisson's ratio Poisson's ratio-1 may be identified as the anisotropic optimal cell layout. Also, from among the plurality of Poisson's ratios, a fourth Poisson's ratio Poisson's ratio-4 may be identified as the maximum Poisson's ratio, and a fourth cell layout 10-4 corresponding to the fourth Poisson's ratio Poisson's ratio-4 may be identified as the isotropic optimal cell layout. Here, the isotropic optimal cell layout may mean a cell layout that minimizes buckling in an isotropic cell array region, and the anisotropic optimal cell layout may mean a cell layout that minimizes buckling in an anisotropic cell array region.

The buckling suppression force of a 2-dimensional structure may be determined based on Equation 3 below.

$${P}_{bu ckling} = \frac{{π}^{2} D}{{{k}^{2} ( A / B )}^{2}} \qquad [ Equation 3 ]$$

In Equation 3, P_{buckling} may denote the buckling critical load, D may denote the stiffness of the 2-dimensional structure, k may denote the boundary condition coefficient of the 2-dimensional structure, and A/B may denote the 2D aspect ratio of the 2-dimensional structure. Here, the buckling critical load refers to the minimum load value needed for buckling to occur. Therefore, a high buckling critical load of a 2-dimensional structure may mean that the buckling suppression force of the 2-dimensional structure is high. In Equation 3, the 2D aspect ratio A/B may only have a value greater than or equal to 1. Therefore, to obtain a high buckling critical load, the 2D aspect ratio A/B may have a value close to 1.

Since the 2D aspect ratio of an isotropic cell array region is already 1 (or 1:1), it may be desirable to minimize the 2D deformation of the isotropic cell array region due to thermal stress to form a cell array region with a high buckling critical load. Therefore, for a memory device including an isotropic cell array region, a cell layout corresponding to the maximum Poisson's ratio may be identified as an isotropic optimal cell layout.

Conversely, since the 2D aspect ratio of an anisotropic cell array region is R (R is a real number greater than 1) (or 1:R), it may be desirable to induce a 2D deformation of the anisotropic cell array region due to thermal stress to form a cell array region with a high buckling critical load. In other words, it may be desirable to induce a 2-dimensional deformation due to thermal stress such that the 2D aspect ratio of the anisotropic cell array region is deformed to be close to 1 (or 1:1). Therefore, for a memory device including an anisotropic cell array region, a cell layout corresponding to the minimum Poisson's ratio may be identified as an anisotropic optimal cell layout.

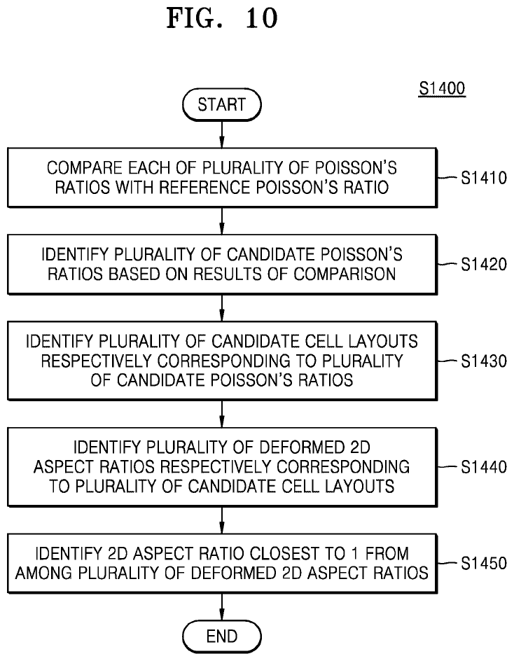

As described above, a method of designing a layout according to some implementations may quickly identify a cell layout capable of minimizing buckling of a cell array region of a memory device based only on a Poisson ratio. A method of designing a layout according to some implementations may identify an optimal cell layout by performing more precise simulations. Detailed descriptions thereof will be given below with reference to FIGS. 10 to 13B.

FIG. 10 is a flowchart for describing a method S1400 of identifying an optimal cell layout, according to some implementations.

Referring to FIG. 10, in operation S1410, each of a plurality of Poisson's ratios may be compared with a reference Poisson's ratio.

Here, the “reference Poisson's ratio” is a value set to identify a plurality of candidate Poisson's ratios and may be determined based on various methods. For example, the reference Poisson's ratio may be a Poisson's ratio corresponding to a cell layout applied to a commercial memory device. In another example, the reference Poisson's ratio may be the mean or the median of a plurality of Poisson's ratios. In another example, the reference Poisson's ratio may be an arbitrary value determined by a designer. The examples described above are merely examples for convenience of explanation, and methods of determining the reference Poisson's ratio is not limited thereto.

Next, in operation S1420, based on a comparison result, the plurality of candidate Poisson's ratios may be identified.

According to some implementations, when the memory device includes an isotropic cell array region, from among a plurality of Poisson's ratios, a plurality of Poisson's ratios greater than the reference Poisson's ratio may be identified as candidate Poisson's ratios. According to some implementations, when the memory device includes an anisotropic cell array region, from among a plurality of Poisson's ratios, a plurality of Poisson's ratios that are less than the reference Poisson's ratio may be identified as candidate Poisson's ratios.

Next, in operation S1430, a plurality of candidate cell layouts respectively corresponding to the plurality of candidate Poisson's ratios may be identified.

For example, referring back to FIG. 9, when the reference Poisson's ratio is 0.212 and the memory device includes an anisotropic cell array region, the first Poisson's ratio Poisson's ratio-1 and a third Poisson's ratio Poisson's ratio-3 less than the reference Poisson's ratio may be identified as candidate Poisson's ratios, and the first cell layout 10-1 and a third cell layout may each be identified as a candidate cell layout. In another example, when the reference Poisson's ratio is 0.212 and the memory device includes an isotropic cell array region, a second Poisson's ratio Poisson's ratio-2 and the fourth Poisson's ratio Poisson's ratio-4 greater than the reference Poisson's ratio may be identified as candidate Poisson's ratios, and a second cell layout 10-2 and a fourth cell layout may each be identified as a candidate cell layout.

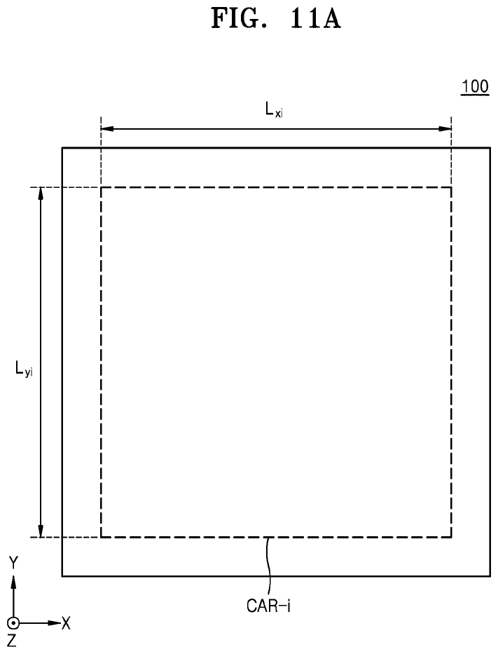

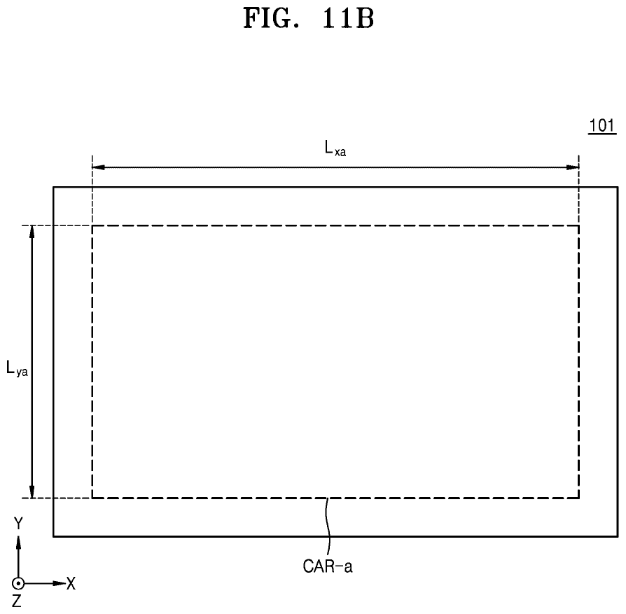

Next, in operation S1440, a plurality of deformed 2D aspect ratios respectively corresponding to the plurality of candidate cell layouts may be identified. The process of identifying a plurality of deformed 2D aspect ratios respectively corresponding to a plurality of candidate cell layouts may be performed based on performing a plurality of simulations. Detailed descriptions thereof will be given below with reference to FIGS. 11A to 13B.

Next, in operation S1450, from among the plurality of transformed 2D aspect ratios, a 2D aspect ratio closest to 1 may be identified. A candidate cell layout corresponding to the 2D aspect ratio closest to 1 may be identified as the optimal cell layout.

As described above, a method of designing a layout according to some implementations may determine an optimal cell layout by considering not only a Poisson's ratio, but also deformed 2D aspect ratios respectively corresponding to a plurality of candidate cell layouts, thereby more accurately identifying a cell layout having a high buckling suppression force. Descriptions of the drawings below will focus on details of a method for identifying deformed 2D aspect ratios respectively corresponding to a plurality of candidate cell layouts.

FIGS. 11A and 11B are cross-sectional views for describing a cell array region of a memory device according to some implementations.

Referring to FIGS. 11A and 11B, a first memory device 100 may include an isotropic cell array region CAR-i, and a second memory device 101 may include an anisotropic cell array region CAR-a. In detail, a width Lₓᵢ of the isotropic cell array region CAR-i in the first horizontal direction may be substantially equal to a width L_{yi} of the isotropic cell array region CAR-i in the second horizontal direction. A first horizontal direction width Lₓₐ of the anisotropic cell array region CAR-a may differ from a second horizontal direction width L_{ya} of the anisotropic cell array region CAR-a.

Within the isotropic cell array region CAR-i and the anisotropic cell array region CAR-a, a plurality of cells may be arranged in a 2-dimensional array form. For example, when the first memory device 100 and the second memory device 101 are 3D NAND flash memory devices, a plurality of channel hole structures (or a plurality of vertical channel structures) may be arranged in a 2-dimensional array form in the isotropic cell array region CAR-i and the anisotropic cell array region CAR-a.

For example, in detail, when the first cell layout 10-1 is determined as an optimal cell layout corresponding to the isotropic cell array region CAR-i, a plurality of channel hole structures may be formed in a 2-dimensional array form corresponding to the first cell layout 10-1 within the isotropic cell array region CAR-i through a high aspect ratio anisotropic etching process. In another example, when an N-th cell layout 10-N is determined as an optimal cell layout corresponding to the anisotropic cell array region CAR-a, a plurality of channel hole structures may be formed in a 2-dimensional array form corresponding to the N-th cell layout 10-N within the anisotropic cell array region CAR-a through a high aspect ratio anisotropic etching process.

In the above description, although a plurality of cells may be formed/arranged in a two-dimensional array form, it is also true that each of the plurality of cells may be formed/arranged by extending in the vertical direction (Z direction). Although, in the above description, a plurality of cells formed in a 2-dimensional array form may be arranged in each of the isotropic cell array region CAR-i and the anisotropic cell array region CAR-a, it is also possible for a stack separation insulation structure region to be formed for electrical isolation of stacked word lines to exist within the isotropic cell array region CAR-i and the anisotropic cell array region CAR-a. Also, from among the entire 2-dimensional areas of the first memory device 100 and the second memory device 101, areas such as a word line contact area and a peripheral circuit contact area may be arranged in areas other than the isotropic cell array region CAR-i and the anisotropic cell array region CAR-a.

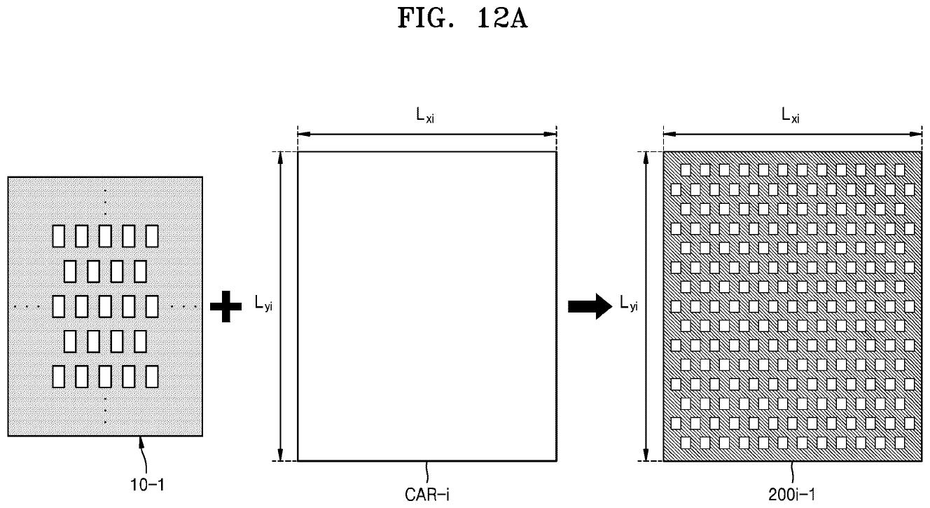

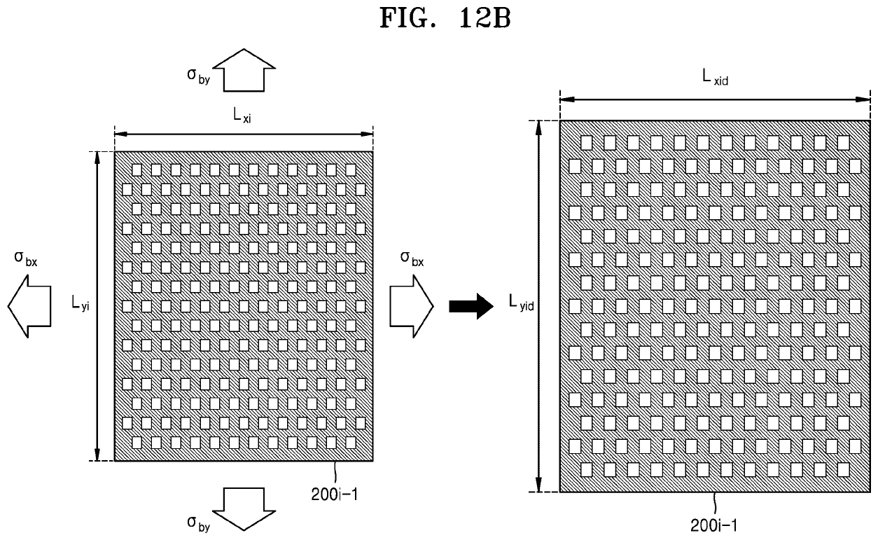

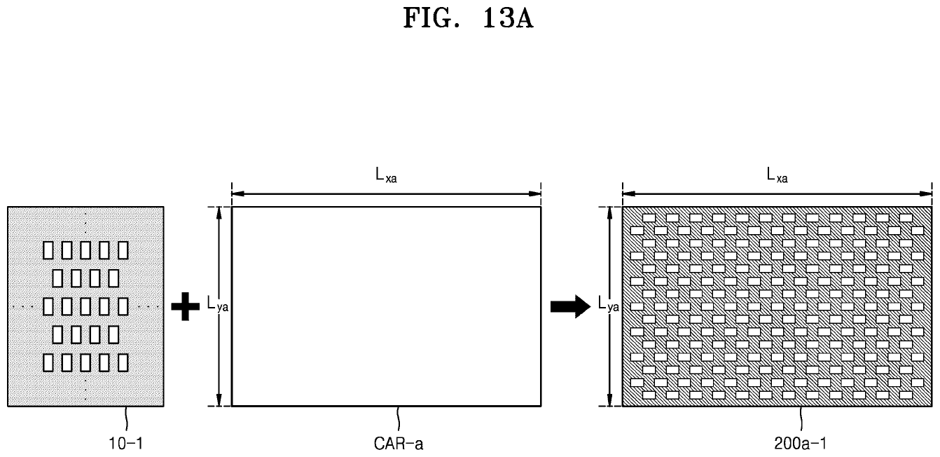

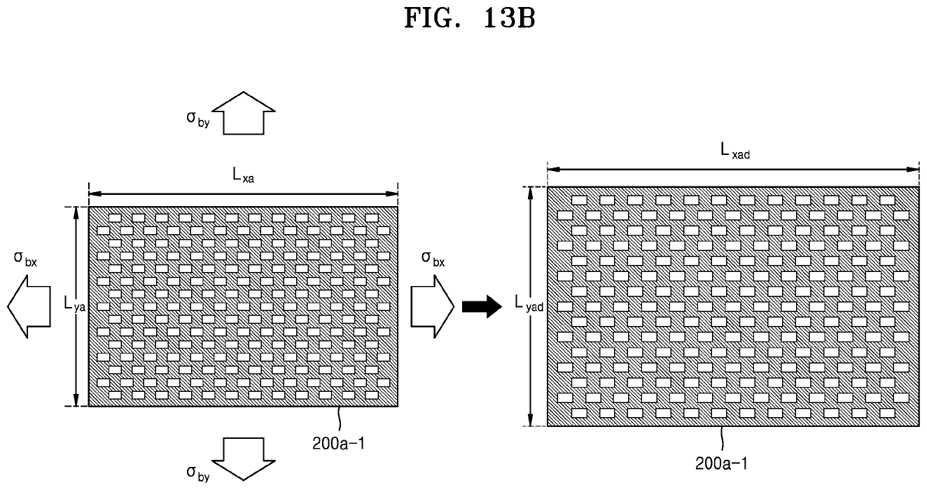

In the descriptions of FIGS. 6 to 9, it is explained only that the optimal cell layout corresponding to each of the isotropic cell array region CAR-i and the anisotropic cell array region CAR-a may be determined based only on a Poisson's ratio. In the descriptions of FIGS. 12A to 13B below, it will be explained that the degree of 2-dimensional thermal deformation that may occur in an actual cell array region may be predicted based on the execution of a simulation that simulates the phenomenon of applying a biaxial tensile load, and that an optimal cell layout corresponding to a particular cell array region may be more precisely identified (or determined) based on a prediction result.

FIGS. 12A to 13B are plan views for describing a method of identifying a deformed 2D aspect ratio, according to some implementations.

Referring to FIGS. 12A to 13B, a 2-dimensional cell array corresponding to a candidate cell layout may be generated, and a deformed 2D aspect ratio may be identified based on performing a simulation targeting the 2-dimensional cell array. In the example implementations shown in FIGS. 12A to 13B, the descriptions will be given assuming that the first cell layout 10-1 is a candidate cell layout.

As shown in FIG. 12A, an isotropic 2-dimensional cell array 200i-1 may be generated based on the first cell layout 10-1 and the isotropic cell array region CAR-i. The isotropic 2-dimensional cell array 200i-1 may be a structure in which a plurality of cells are arranged in the isotropic cell array region CAR-i in a 2-dimensional arrangement form corresponding to the first cell layout 10-1. The width Lₓᵢ of the isotropic 2-dimensional cell array 200i-1 in the first horizontal direction may be substantially equal to the width L_{yi} of the isotropic 2-dimensional cell array 200i-1 in the second horizontal direction.

Next, as shown in FIG. 12B, by performing a simulation targeting the isotropic 2-dimensional cell array 200i-1, the deformed 2D aspect ratio of the isotropic 2-dimensional cell array 200i-1 may be identified. The simulation may be a simulation that simulates the phenomenon of applying a biaxial tensile loading to the isotropic 2-dimensional cell array 200i-1. The biaxial tensile loading may include a first horizontal direction load σ_{bx} and a second horizontal direction load σ_{by}. Here, the first horizontal load σ_{bx} and the second horizontal load σ_{by} may be substantially equal, where substantially equal can refer to the load in the first horizontal direction being equal to the load in the second horizontal direction or the difference between the load in the first direction and the load in the second direction is less than 5% of the either one of the load in the first direction and the load in the second direction.

According to some implementations, a simulation simulating a phenomenon of applying a biaxial tensile loading may be performed based on a finite element method. However, the simulation method is not limited to finite element method simulations, and may include simulation methods based on various numerical analysis techniques such as a finite volume simulation method and a finite difference simulation method.

When a biaxial tensile loading is applied to the isotropic 2-dimensional cell array 200i-1, the width Lₓᵢ of the isotropic 2-dimensional cell array 200i-1 in the first horizontal direction and the width L_{yi} of the isotropic 2-dimensional cell array 200i-1 in the second horizontal direction may be deformed. For example, the isotropic 2-dimensional cell array 200i-1 may have a first deformed width L_{xid} in the first horizontal direction and a second deformed width L_{yid} in the second horizontal direction. The deformed 2D aspect ratio of the isotropic 2-dimensional cell array 200i-1 may be determined based on the first deformed width L_{xid} and the second deformed width L_{yid} of the isotropic 2-dimensional cell array 200i-1.

According to some implementations, the second deformed width L_{yid} may be greater than the first deformed width L_{xid}, in which case the deformed 2D aspect ratio of the isotropic 2-dimensional cell array 200i-1 may be a length ratio

$$\frac{{L}_{yid}}{{L}_{xid}}$$

of the second deformed width L_{yid} with respect to the first deformed width L_{xid}. According to some implementations, the first deformed width L_{xid} may be greater than the second deformed width L_{yid}, in which case the deformed 2D aspect ratio of the isotropic 2-dimensional cell array 200i-1 may be a length ratio

$$\frac{{L}_{xid}}{{L}_{yid}}$$

of the first deformed width L_{xid} with respect to the second deformed width L_{yid}.

As shown in FIG. 13A, an anisotropic 2-dimensional cell array 200a-1 may be generated based on the first cell layout 10-1 and the anisotropic cell array region CAR-a. The anisotropic 2-dimensional cell array 200a-1 may be a structure in which a plurality of cells are arranged in a 2-dimensional arrangement corresponding to the first cell layout 10-1 in an anisotropic cell array region CAR-a. The first horizontal direction width Lₓₐ of the anisotropic 2-dimensional cell array 200a-1 may be different from the second horizontal direction width L_{ya} of the anisotropic 2-dimensional cell array 200a-1.

Next, as shown in FIG. 13B, by performing a simulation targeting the anisotropic 2-dimensional cell array 200a-1, the deformed 2D aspect ratio of the anisotropic 2-dimensional cell array 200a-1 may be identified. As described above in the description of FIG. 12B, by performing the simulation, a biaxial tensile loading including the first horizontal load σ_{bx} and the second horizontal load σ_{by} may be applied to the anisotropic 2-dimensional cell array 200a-1.

When a biaxial tensile loading is applied to the anisotropic 2-dimensional cell array 200a-1, the first horizontal direction width Lₓₐ and the second horizontal direction width L_{ya} of the anisotropic 2-dimensional cell array 200a-1 may be deformed. For example, the anisotropic 2-dimensional cell array 200a-1 may have a first deformed width L_{xad} in the first horizontal direction and a second deformed width L_{yad} in the second horizontal direction. The deformed 2D aspect ratio of the anisotropic 2-dimensional cell array 200a-1 may be determined based on the first deformed width L_{xad} and the second deformed width L_{yad} of the anisotropic 2-dimensional cell array 200a-1. According to some implementations, the second deformed width L_{yad} may be greater than the first deformed width L_{xad}, in which case the deformed 2D aspect ratio of the anisotropic 2-dimensional cell array 200a-1 may be a length ratio

$$\frac{{L}_{yad}}{{L}_{xad}}$$

of the second deformed width L_{yad} to the first deformed width L_{xad}. According to some implementations, the first deformed width L_{xad} may be greater than the second deformed width L_{yad}, in which case the deformed 2D aspect ratio of the anisotropic 2-dimensional cell array 200a-1 may be a length ratio

$$\frac{{L}_{xad}}{{L}_{yad}}$$

of the first deformed width L_{xad} with respect to the second deformed width L_{yad}.

In the description of FIGS. 12A to 13B, only the case where the first cell layout 10-1 is a candidate cell layout is exemplified, but simulations based on the same/similar principles may be performed for each of a plurality of candidate cell layouts, and a plurality of deformed 2D aspect ratios respectively corresponding to the plurality of candidate cell layouts may be identified.

A method of designing a layout and a method of manufacturing a mask, according to some implementations, may precisely predict the degree of 2-dimensional thermal deformation that may occur when a particular cell layout is applied to a cell array region by performing a biaxial tensile loading simulation for a 2-dimensional cell array. In particular, rather than performing the biaxial tensile loading simulation for each of all prepared cell layouts, the methods may identify a plurality of candidate cell layouts based on the Poisson's ratio and perform the biaxial tensile loading simulation only for each of a plurality of identified candidate cell layouts, thereby enabling identification of an optimal cell layout more quickly.

FIG. 14 is a flowchart showing a method S1500 of manufacturing a mask according to some implementations.

Referring to FIG. 14, in operation S1510, an Optical Proximity Correction (OPC) for an optimal cell layout may be performed, and thus an OPC optimal cell layout may be obtained. Here, an optimal cell layout may be obtained based on the method of designing a layout described above in detail in the descriptions of FIGS. 2 to 13B.

As patterns become finer, the optical proximity effect (OPE) due to the influence between neighboring patterns may occur during an exposure process. The OPC method is a method of suppressing the occurrence of an OPE by correcting a mask layout to overcome the optical proximity phenomenon. The OPC method may include processes such as generating an optical image for a corresponding pattern, generating an OPC model, and obtaining an image or data regarding a layout through simulation using the OPC model.

During the execution of the OPC method, an optical OPC model may be generated. The generation of the optical OPC model may include optimization of a defocus stand (DS) position, a best focus (BF) position, etc. in an exposure process. Also, the generation of the optical OPC model may include generation of an optical image in consideration of the diffraction phenomenon of light or an optical state of an exposure equipment. Of course, the generation of an optical OPC model is not limited to the descriptions given above. For example, the generation of an optical OPC model may include various technical features related to optical phenomena during an exposure process.

After generating the optical OPC model, an OPC model regarding photoresist (PR) may be generated. The generation of an OPC model for the PR may include optimization of the threshold of the PR. Here, the threshold value of the PR refers to the threshold value at which a chemical change occurs during an exposure process. For example, the threshold value may be given as the intensity of exposure light. The generation of an OPC model for the PR may also include selection of an appropriate model form from among several PR model forms.

Generally, the optical OPC model and the OPC model for the PR are collectively referred to as an OPC model. After the OPC model is generated, simulation is repeatedly performed using the OPC model. The simulation may be performed until a certain condition is satisfied. For example, a root mean square (RMS), EPE, and reference number of repetitions for a CD error may be used as conditions for repeating a simulation. According to the method of manufacturing a mask, according to some implementations, OPC-ed optimal cell layout data may be obtained by performing a simulation using an OPC model.

Next, in operation S1520, the OPC-ed optimal cell layout data may be transmitted to a mask manufacturing team as MTO design data. In general, mask tape out (MTO) may refer to handing over data regarding a final mask data obtained through an OPC method to the mask manufacturing team to request manufacturing of a mask. Therefore, the MTO design data may be substantially identical to OPC-ed optimal cell layout data. Such MTO design data may have a graphic data format used in electronic design automation (EDA) software, etc. For example, the MTO design data may have a data format such as Graphic Data System II (GDS2), Open Artwork System Interchange Standard (OASIS), etc.

Next, in operation S1530, mask data may be prepared based on the MTO design data. The MDP may include, for example, i) format conversion, called fracturing, ii) augmentation of barcodes for mechanical reading, a standard mask pattern for inspection, a job deck, etc., and iii) automatic and manual verification. Here, a job-deck may refer to generation of a text file regarding a series of instructions such as arrangement information of multiple mask files, a standard dose, and a speed or a method of exposure.

Meanwhile, the format conversion, i.e., fracturing, may refer to a process of dividing MTO design data into respective regions and converting the MTO design data to a format for electron beam exposure equipment. The fracturing may include data manipulation, such as scaling, sizing of data, rotating of data, reflecting a pattern, and inverting colors. During a conversion process through fracturing, data regarding a large number of systematic errors that may occur somewhere during transmission from design data to an image on a wafer may be corrected. The process of correction of data regarding systematic errors is called mask process correction (MPC) and may include, for example, a task for adjusting a line width called CD adjustment and a task for improving pattern placement precision. Therefore, the fracturing may contribute to improving the quality of a final mask and may also be a process that is performed in advance for mask process correction. Here, the systematic errors may be caused by distortions occurring in an exposure process, a mask development and etching process, and a wafer imaging process.

In addition, the MDP may include the MPC. As described above, the MPC refers to a process of correcting errors that occur during an exposure process, that is, systematic errors. Here, the exposure process may be an overall concept that includes electron beam writing, development, etching, baking, etc. Also, data processing may be performed prior to the exposure process. The data processing is a preprocessing process regarding mask data and may include grammar check for mask data, exposure time prediction, etc. Through the preparation of the mask data, E-beam data to expose a mask substrate may be generated.

Next, in operation S1540, a mask may be fabricated based on the mask data. The manufacturing of a mask may include an exposure process, a development process, an etching process, a cleaning process, a measurement process, a defect inspection or defect repair process, etc. with respect to a mask substrate. Also, the manufacturing of a mask may include a pellicle application process. Here, the pellicle application process may refer to a process of attaching pellicles to a mask surface to protect a mask from subsequent contamination during delivery and during the useful life of the mask when it is confirmed that there are no contaminant particles or chemical stains through final cleaning and inspection.

While the disclosure has been particularly shown and described with reference to implementations thereof, it will be understood that various changes in form and details may be made therein without departing from the spirit and scope of the following claims.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A method of designing a layout of a memory device, the method comprising:
identifying a plurality of unit cell pattern structures respectively corresponding to a plurality of cell layouts;
identifying a plurality of Poisson's ratios respectively corresponding to the plurality of unit cell pattern structures; and
identifying an isotropic optimal cell layout from among the plurality of cell layouts based on the plurality of Poisson's ratios,
wherein the identifying the isotropic optimal cell layout comprises
identifying a maximum Poisson's ratio from among the plurality of Poisson's ratios; and
identifying, from among the plurality of cell layouts, a cell layout corresponding to the maximum Poisson's ratio as the isotropic optimal cell layout,
and
a plurality of horizontal cell pitches respectively corresponding to the plurality of cell layouts are substantially identical.

2. The method of claim 1, wherein identifying the plurality of unit cell pattern structures comprises:
identifying a plurality of repeating patterns respectively corresponding to the plurality of cell layouts; and
identifying the plurality of unit cell pattern structures based on each repeating pattern of the plurality of repeating patterns, wherein
a number of cells per unit area included in each unit cell pattern structure is substantially identical across the plurality of unit cell pattern structures.

3. The method of claim 1, wherein identifying the isotropic optimal cell layout from among the plurality of cell layouts comprises:
identifying a plurality of candidate Poisson's ratios from among the plurality of Poisson's ratios, wherein each Poisson's ratio of the plurality of candidate Poisson's ratios is greater than a reference Poisson's ratio;
identifying a plurality of candidate cell layouts respectively corresponding to the plurality of candidate Poisson's ratios from among the plurality of cell layouts;
identifying a plurality of deformed 2D aspect ratios respectively corresponding to the plurality of candidate cell layouts;
identifying a 2D aspect ratio closest to 1 from among the plurality of deformed 2D aspect ratios; and
identifying, from among the plurality of candidate cell layouts, a candidate cell layout corresponding to the 2D aspect ratio closest to 1 as the isotropic optimal cell layout.

4. The method of claim 3, wherein identifying the 2D aspect ratio from the plurality of deformed 2D aspect ratios comprises:
generating a plurality of 2-dimensional cell arrays respectively corresponding to the plurality of candidate cell layouts; and
performing a plurality of simulations respectively targeting the plurality of 2-dimensional cell arrays to respectively identify the plurality of deformed 2D aspect ratios,
each 2-dimensional cell array of the plurality of 2-dimensional cell arrays is a structure comprising a plurality of cells arranged in an isotropic cell array region in a 2-dimensional arrangement form corresponding to each candidate cell layout of the plurality of candidate cell layouts.

5. The method of claim 4, wherein performing the plurality of simulations to identify the plurality of deformed 2D aspect ratios comprises:
applying a biaxial tensile loading to the plurality of 2-dimensional cell arrays through the plurality of simulations, respectively; and
identifying a ratio of a length of each 2-dimensional cell array of the plurality of 2-dimensional cell arrays in a second horizontal direction to a length of each 2-dimensional cell array of the plurality of 2-dimensional cell arrays in a first horizontal direction as each deformed 2D aspect ratio of the plurality of deformed 2D aspect ratios,
wherein the biaxial tensile loading includes a loading in the first horizontal direction and a loading in the second horizontal direction, and
the loading in the first horizontal direction and the loading in the second horizontal direction are substantially equal.

6. The method of claim 1, wherein identifying the plurality of Poisson's ratios comprises
performing a plurality of simulations respectively targeting the plurality of unit cell pattern structures, and
each simulation of the plurality of simulations simulates a phenomenon of applying a uniaxial tensile loading to each unit cell pattern structure of the plurality of unit cell pattern structures.

7. The method of claim 6, wherein performing the plurality of simulations comprises:
dividing each unit cell pattern structure of the plurality of unit cell pattern structures into a plurality of finite elements; and
performing a numerical analysis on each finite element of the plurality of finite elements.

8. The method of claim 1, wherein the identifying of the plurality of Poisson's ratios comprises
identifying the plurality of Poisson's ratios respectively corresponding to the plurality of unit cell pattern structures based on an analytical method, and
the analytical method comprises analyzing the plurality of unit cell pattern structures by approximating the plurality of unit cell pattern structures as a bar model.

9. The method of claim 8, wherein each unit cell pattern structure of the plurality of unit cell pattern structures includes a plurality of cells, and
the bar model comprises two cells adjacent to each other from among the plurality of cells connected to each other with a 2-dimensional bar.

10. A method of designing a layout of a memory device, the method comprising:
identifying a plurality of unit cell pattern structures respectively corresponding to a plurality of cell layouts;
identifying a plurality of Poisson's ratios respectively corresponding to the plurality of unit cell pattern structures; and
identifying an anisotropic optimal cell layout from among the plurality of cell layouts based on the plurality of Poisson's ratios,
wherein identifying the anisotropic optimal cell layout comprises:
identifying a minimum Poisson's ratio from among the plurality of Poisson's ratios; and
identifying, from among the plurality of cell layouts, a cell layout corresponding to the minimum Poisson's ratio as the anisotropic optimal cell layout,
a 2D aspect ratio of a horizontal cross-section of an anisotropic cell array region is 1:R, wherein R is a real number greater than 1, and
a plurality of horizontal cell pitches respectively corresponding to the plurality of cell layouts are substantially identical.

11. The method of claim 10, wherein identifying the plurality of unit cell pattern structures comprises:
identifying a plurality of repeating patterns respectively corresponding to the plurality of cell layouts; and
identifying the plurality of unit cell pattern structures based on each repeating pattern of the plurality of repeating patterns, wherein
a number of cells per unit area included in each unit cell pattern structure is substantially identical across the plurality of unit cell pattern structures.

12. The method of claim 10, wherein identifying the anisotropic optimal cell layout from among the plurality of cell layouts comprises:
identifying a plurality of candidate Poisson's ratios that are less than a reference Poisson's ratio from among the plurality of Poisson's ratios;
identifying a plurality of candidate cell layouts respectively corresponding to the plurality of candidate Poisson's ratios from among the plurality of cell layouts;
identifying a plurality of deformed 2D aspect ratios respectively corresponding to the plurality of candidate cell layouts;
identifying a 2D aspect ratio closest to 1 from among the plurality of deformed 2D aspect ratios; and
identifying, from among the plurality of candidate cell layouts, a candidate cell layout corresponding to the 2D aspect ratio closest to 1 as the anisotropic optimal cell layout.

13. The method of claim 12, wherein identifying the 2D aspect ratio from among the plurality of deformed 2D aspect ratios comprises:
generating a plurality of 2-dimensional cell arrays respectively corresponding to the plurality of candidate cell layouts; and
performing a plurality of simulations respectively targeting the plurality of 2-dimensional cell arrays to respectively identify the plurality of deformed 2D aspect ratios, wherein
each 2-dimensional cell array of the plurality of 2-dimensional cell arrays is a structure in which a plurality of cells are arranged in the anisotropic cell array region in a 2-dimensional arrangement form corresponding to each candidate cell layout of the plurality of candidate cell layouts.

14. The method of claim 13, wherein performing the plurality of simulations to identify the plurality of deformed 2D aspect ratios comprises:
applying a biaxial tensile loading to the plurality of 2-dimensional cell arrays through the plurality of simulations, respectively; and
identifying a ratio of a length of each 2-dimensional cell array of the plurality of 2-dimensional cell arrays in a second horizontal direction to a length of each 2-dimensional cell array of the plurality of 2-dimensional cell arrays in a first horizontal direction as each deformed 2D aspect ratio of the plurality of deformed 2D aspect ratios,
wherein the biaxial tensile loading includes a loading in the first horizontal direction and a loading in the second horizontal direction, and
the loading in the first horizontal direction is substantially equal to the loading in the second horizontal direction.

15. The method of claim 10, wherein identifying the plurality of Poisson's ratios comprises
performing a plurality of simulations respectively targeting the plurality of unit cell pattern structures, wherein
each simulation of the plurality of simulations simulates a phenomenon of applying a uniaxial tensile loading to each unit cell pattern structure of the plurality of unit cell pattern structures.

16. The method of claim 15, wherein performing the plurality of simulations comprises:
dividing each unit cell pattern of the plurality of unit cell pattern structures into a plurality of finite elements; and
performing a numerical analysis on each finite element of the plurality of finite elements.

17. The method of claim 10, wherein identifying the plurality of Poisson's ratios comprises
identifying the plurality of Poisson's ratios respectively corresponding to the plurality of unit cell pattern structures based on an analytical method, wherein
the analytical method comprises analyzing the plurality of unit cell pattern structures by approximating the plurality of unit cell pattern structures as a bar model.

18. The method of claim 17, wherein each unit cell pattern structure of the plurality of unit cell pattern structures includes a plurality of cells, and
the bar model comprises two cells adjacent to each other from among the plurality of cells connected to each other with a 2-dimensional bar.

19. A method of manufacturing a mask, the method comprising:
preparing a plurality of cell layouts satisfying a horizontal cell pitch of a memory device;
identifying a plurality of unit cell pattern structures respectively corresponding to the plurality of cell layouts based on repeating patterns of the plurality of cell layouts;
identifying a plurality of Poisson's ratios respectively corresponding to the plurality of unit cell pattern structures;
identifying an optimal cell layout for the memory device from among the plurality of cell layouts based on the plurality of Poisson's ratios; and
manufacturing a mask corresponding to the optimal cell layout,
wherein identifying the optimal cell layout comprises
for an isotropic cell array region of the memory device,
identifying a maximum Poisson's ratio from among the plurality of Poisson's ratios, and
identifying, from among the plurality of cell layouts, a cell layout corresponding to the maximum Poisson's ratio as the optimal cell layout,
or, for an anisotropic cell array region of the memory device,
identifying a minimum Poisson's ratio from among the plurality of Poisson's ratios, and
identifying, from among the plurality of cell layouts, a cell layout corresponding to the minimum Poisson's ratio as the optimal cell layout.

20. The method of claim 19, wherein identifying the plurality of unit cell pattern structures comprises:
identifying a plurality of repeating patterns respectively corresponding to the plurality of cell layouts; and
identifying the plurality of unit cell pattern structures based on each repeating pattern of the plurality of repeating patterns, wherein
identifying of the plurality of Poisson's ratios comprises
performing a plurality of simulations respectively targeting the plurality of unit cell pattern structures,
a number of cells per unit area included in each unit cell pattern structure is substantially identical across the plurality of unit cell pattern structures, and
each simulation of the plurality of simulations simulates a phenomenon of applying a uniaxial tensile loading to each unit cell pattern structure of the plurality of unit cell pattern structures.
